(19) United States
(12) Patent Application Publication
(10) Pub. No.: US 2022/0236775 A1
(43) Pub. Date: Jul. 28, 2022

(54) FIXING STRUCTURE FOR HARD DISK AND SERVER CHASSIS HAVING THE SAME

(71) Applicant: HONGFUJIN PRECISION ELECTRONICS(TIANJIN)CO.,LTD., Tianjin (CN)

(72) Inventors: HAN-YU LI, New Taipei (TW); WEN-HU LU, Tianjin (CN); CHEN XING, Tianjin (CN); SHU-YING CEN, Tianjin (CN)

(21) Appl. No.: 17/515,039

(22) Filed: Oct. 29, 2021

(30) Foreign Application Priority Data
Jan. 22, 2021 (CN) 202110088601.2

(51) Int. Cl. G06F 1/18; G11B 33/12

(52) U.S. Cl. CPC G06F 1/187; G11B 2220/2516; G11B 33/124

(57) ABSTRACT

A fixing structure for a hard disk is provided, which includes a main body, a rotation member, and at least one latching post. The main body includes two first sidewalls and a second sidewall connecting therebetween. The main body defines a groove for receiving the hard disk. At least one first sidewall defines a limiting slot. The rotation member includes two rotation arms, at least one rotation arm defines a latching slot. The rotation arms are rotatably connected to the two first sidewalls, to cause the fixing structure to be capable of switching between a first state and a second state. Each latching post is movably disposed in one limiting slot and one latching slot. When the fixing structure is switched between the first direction and the second state, the main body can move along a first direction or a second direction.

### FIELD

The subject matter relates to servers, and more particularly, to a fixing structure for a hard disk and a server chassis having the fixing structure.

### BACKGROUND

When multiple hard disks are placed in a carrier of a server chassis, because of the narrow space in the carrier, it may not be easy to move the hard disks in the carrier and then insert them to a mainboard in the server chassis.

Therefore, there is room for improvement in the art.

### BRIEF DESCRIPTION OF THE DRAWINGS

Implementations of the present technology will now be described, by way of example only, with reference to the attached figures.

FIG. 1 is a diagrammatic view of a fixing structure for a hard disk according to an embodiment of the present disclosure.

FIG. 2 is similar to FIG. 1, but showing the fixing structure in another state.

FIG. 3 is an exploded view of the fixing structure of FIG. 1.

FIG. 4 is a diagrammatic view showing connection between a main body and a rotation member of the fixing structure of FIG. 1.

FIG. 5 is a diagrammatic view showing connection between a main body and a rotation member of the fixing structure of FIG. 2.

FIG. 6 is a diagrammatic view of a server chassis according to an embodiment of the present disclosure.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

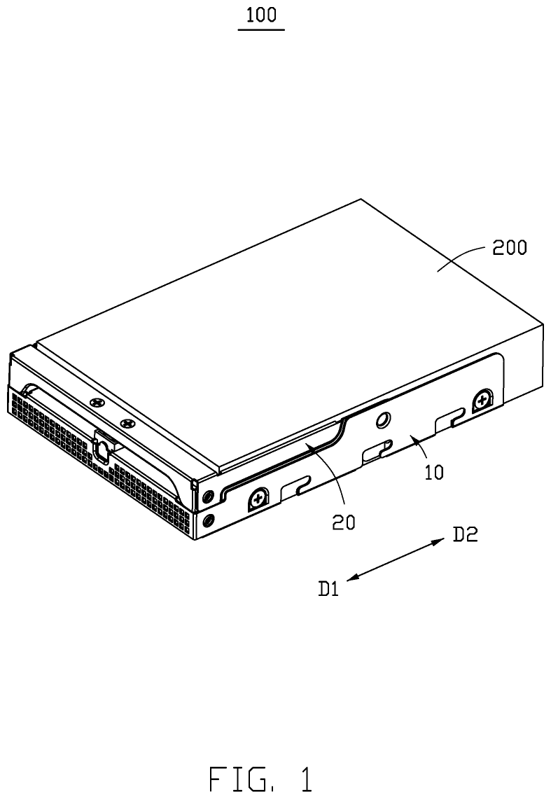

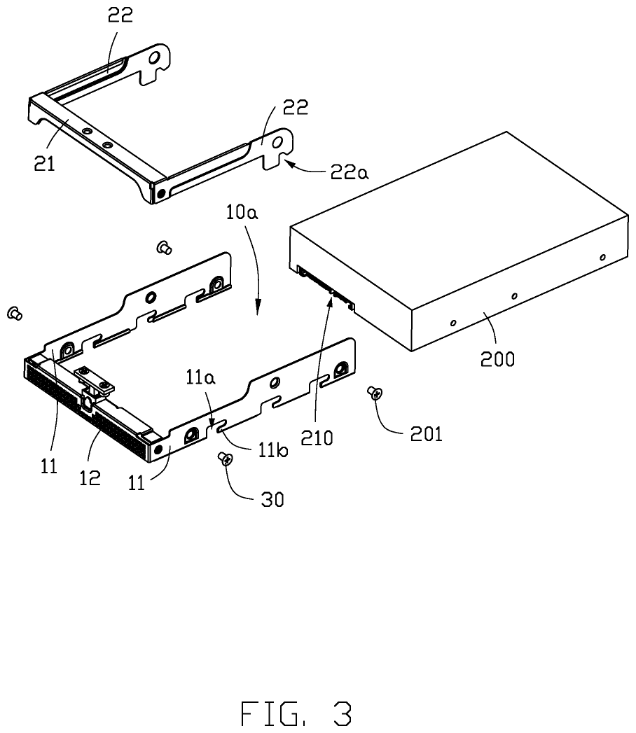

Referring to FIGS. 1 to 3, the fixing structure 100 includes a main body 10 and a rotation member 20. The main body 10 includes two first sidewalls 11 parallel to each other and a second sidewall 12. The second sidewall 12 is perpendicular to the two first sidewalls 11 and connects between the two first sidewalls 11. That is, the first sidewall 11 and second sidewall 12 cooperatively form a U-shaped structure that defining a groove 10a. The hard disk 200 can be inserted into the groove 10a, and then fixed to the two first sidewall 11. In one embodiment, the hard disk 200 are fixed to the two first sidewalls 11 by screw bolts 201. A port 210 of the hard disk 200 faces the second sidewall 12.

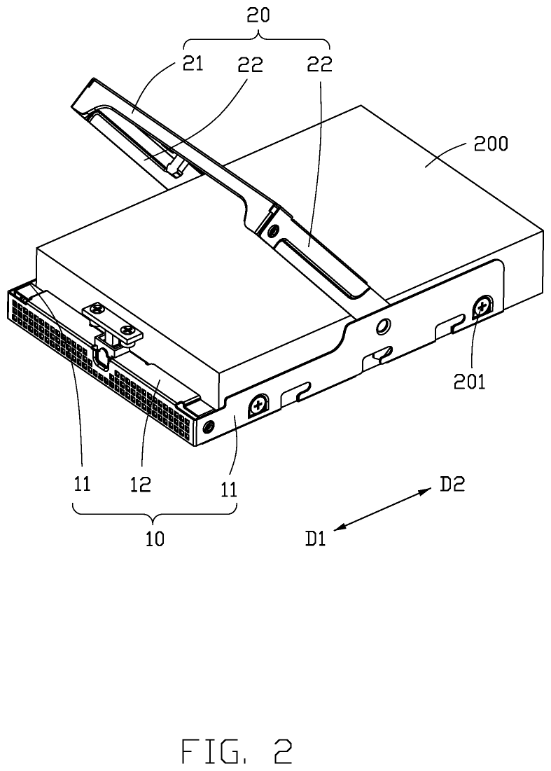

The rotation member 20 includes two rotation arms 22 rotatably connected to the two first sidewalls 11. The rotation axes of the two rotation arms 22 are aligned with each other. As shown in FIG. 1, each rotation arm 22 can rotate to be parallel to an extending direction of the corresponding first sidewall 11 (hereinafter, “first state”). As shown in FIG. 2, each rotation arm 22 can also rotate to be angled with the corresponding first sidewall 11 (hereinafter, “second state”). In the second state, the angle between the rotation arm 22 and the corresponding first sidewall 11 is not equal to 0 degree or 180 degrees. A direction from each first sidewall 11 to the second sidewall 12 is defined as a first direction D1, and an opposite direction is defined as a second direction D2. Each of the first and the second directions D1, D2 are parallel to the extending direction of the first sidewalls 11.

In order to facilitate the rotation of the rotation arms 22, the rotation member 20 can also include a handle 21 connecting between the two rotation arms 20. When a user rotates the handle 21, the handle 21 can drive the two rotation arms 20 to rotate. Furthermore, when the user lifts the handle 21 up, the main body 10 and the hard disk 200 fixed thereto can also be lifted up at the same time.

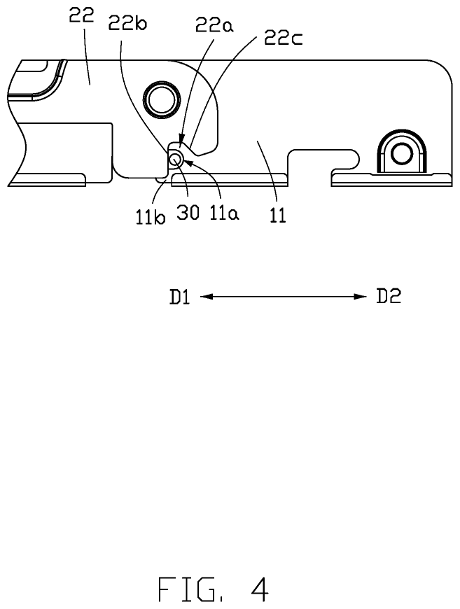

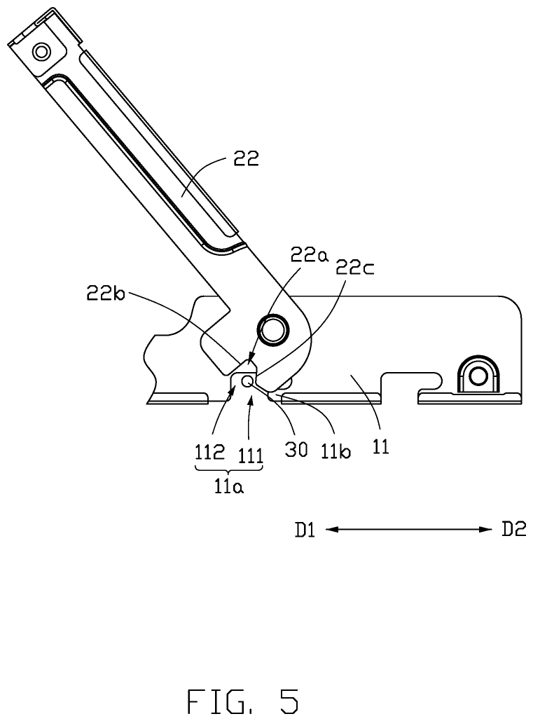

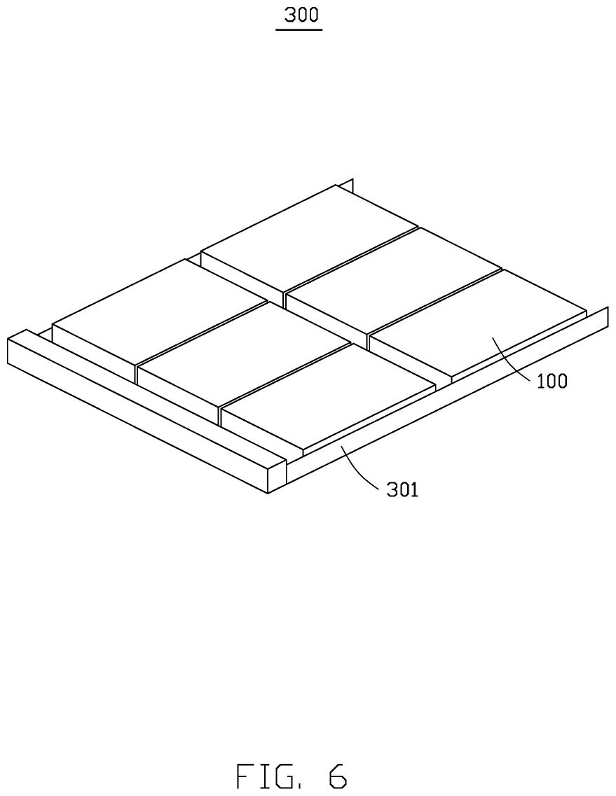

Referring to FIGS. 4 and 5, the fixing structure 100 also includes two latching posts 30. The latching posts 30 are fixed to a carrier 301 of a server chassis 300 (see FIG. 6). That is, the position of the latching posts 30 is fixed. Each first sidewall 11 defines a limiting slot 11a, and each latching post 30 can be movably disposed in one limiting slot 11a. Each rotation arm 22 defines a latching slot 22a. Each latching post 30 can further pass through one latching slot 22a. The latching slot 22a includes a first inner wall 22b and a second inner wall 22c. The first inner wall 22b and the second inner wall 22c form an acute angle therebetween. In one embodiment, the first inner wall 22b is along the vertical direction, and the second inner wall 22c is inclined with respect to the vertical direction.

As shown in FIG. 4, when the fixing structure 100 is in the first state, each first inner wall 22b can abut against a side of one latching post 30, and each limiting slot 11a can abut against another opposite side of the latching post 30. Thus, the hard disk 200 can be fixed in the fixing structure 100. In one embodiment, the handle 21 and the second sidewall 12 can be connected to each other by snap fit or magnetic adsorption, thereby preventing the rotation member 20 from shaking in the first state.

As shown in FIG. 5, when the fixing structure 100 is in the second state, each second inner wall 22c can abut against one latching post 22. In one embodiment, the rotation arms 22 can rotate about 45 degrees to switch between the first state and the second state.

Thus, when the fixing structure 100 is switched from the second state to the first state by rotating the rotation arms 22 towards the main body 10, each first inner wall 22b can abut against one latching post 30, so that the first inner wall 22b can apply a pushing force to the latching post 22. Since the position of the latching post 22 is fixed, an opposite acting force of the pushing force can push the main body 10 and the hard disk 200 fixed thereto to move along the first direction D1. When the fixing structure 100 is switched from the first state to the second state by rotating the rotation arms 22 away from the main body 10, each second inner wall 22c abuts against one latching post 22, so that the second inner wall 22c can apply a pushing force to the latching post 22. Since the position of the latching post 22 is fixed, an opposite acting force of the pushing force can push the main body 10 and the hard disk 200 fixed thereto to move along the second direction D2.

Thus, the rotation of the rotation arms 22 can be converted to the movement of the hard disk 200 along the first direction D1 or the second direction D2.

In use, a user can rotate the handle 21 to cause the rotation arms 22 to be angled with the first sidewalls 11, place the main body 10 and the hard disk 200 into the carrier 301, and insert the latching posts 30 that fixed to the carrier 301 into the latching slots 1a. Then, the rotation arms 22 are rotated back. After the rotation, each first inner wall 22b abuts against one latching post 30, and the hard disk 200 moves along the first direction until port 210 of the hard disk 200 is inserted into another port of a mainboard placed in the carrier 301. At this time, the fixing structure 100 has been switched to the first state. If the user needs to take the hard disk 200 out of the carrier 301, the rotation arms 22 are rotated to be angled with the first sidewalls 11 again. After the rotation, each second inner wall 22c abuts against and pushes the latching post 22 to move out of the limiting slot 11a. Then, the port 210 of the hard disk 200 can be separated from the mainboard, and the hard disk 200 can be taken away by the user.

In one embodiment, each limiting slot 11a includes a first slot portion 111 and a second slot portion 112. The first slot portion 111 passes through a bottom of the corresponding first sidewall 11. The second slot portion 112 communicates with the first slot portion 111. Along the extending direction of the first sidewall 11, the first slot portion 111 is narrower than the second slot portion 112, so that a limiting bar 11b is formed near the bottom of the first sidewall 11. When in the first state, each limiting bar 11b is disposed under one latching post 30, which can prevent the latching post 30 from further moving along the vertical direction as shown in FIG. 4. Thus, the limiting bar 11b can prevent the hard disk 220 from shaking or disengaging from the latching post 30. When the fixing structure 100 is switched from the first state to the second state, the latching post 30 moves out of the limiting slot 11a first through the second slot portion 112 and then through the first slot portion 111.

Referring to FIG. 6, an embodiment of a server chassis 300 is further provided according to the present disclosure. The server chassis 300 includes a carrier 301 and a number of fixing structures 100. The fixing structures 100 can fix a number of hard disks 200 in the carrier 301.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A fixing structure for a hard disk, comprising:
a main body comprising two first sidewalls and a second sidewall connecting between the respectively two first sidewalls, the main body defining a groove among the two first sidewalls and the second sidewall, the groove being configured for fixedly receiving the hard disk, at least one of the two first sidewalls defining a limiting slot, wherein a first direction is defined as a direction from the two first sidewalls to the second sidewall, and a second direction is defined as an opposite direction of the first direction;
a rotation member comprising two rotation arms, at least one of the two rotation arms defining a latching slot, the two rotation arms rotatably connected to the respectively two first sidewalls, the fixing structure is switched between a first state and a second state by the rotation member; and
at least one latching post fixed to a carrier, each of the at least one latching post being movably disposed in a corresponding one of the limiting slot and a corresponding one of the latching slot;
wherein when the fixing structure is switched from the second state to the first state, the two rotation arms are parallel to the first direction, and each of the limiting slot abuts against a corresponding one of the at least one latching post, thereby the main body is movable along the first direction;
wherein when the fixing structure is switched from the first state to the second state, the two rotation arms are angled with the first direction, each of the limiting slot abuts against a corresponding one of the at least one latching post, thereby the main body is movable along the second direction, and each of the at least one latching post is disengaged with the corresponding one of the latching slot.

2. The fixing structure of claim 1, wherein each of the latching slot comprises a first inner wall and a second inner wall, the first inner wall and the second inner wall form an acute angle therebetween; when the fixing structure is switched from the second state to the first state, each first inner wall abuts against a corresponding one of the at least one latching post; when the fixing structure is switched from the first state to the second state, each second inner wall abuts against a corresponding one of the at least one latching post.

3. The fixing structure of claim 1, wherein each of the limiting slot comprises a first slot portion and a second slot portion, each of the first slot portion extends through a bottom of a corresponding one of the two first sidewalls, each of the second slot portion communicates with a corresponding one of the first slot portion, along the first direction, each of the first slot portion is narrower than the corresponding one of the second slot portion, a limiting bar is formed near the bottom of the corresponding one of the two first sidewalls;
when in the first state, each of the limiting bar is disposed under a corresponding one of the latching post; when in the second state, each of the at least one latching post moves through the second slot portion and then through the first slot portion.

4. The fixing structure of claim 1, wherein the two rotation arms rotate about 45 degrees to switch between the first state and the second state.

5. The fixing structure of claim 1, wherein the rotation member further comprises a handle connecting between the two rotation arms.

6. The fixing structure of claim 5, wherein when in the first state, the handle and the second sidewall are connected to each other by snap fit or magnetic adsorption.

7. The fixing structure of claim 1, further comprising at least one screw bolt, wherein each of the at least one screw bolt is configured to fix a corresponding one of the two first sidewall to the hard disk.

8. A server chassis, comprising:
a carrier; and
a plurality of fixing structures disposed on the carrier, each of the plurality of fixing structures comprising:
a main body comprising two first sidewalls and a second sidewall connecting between the respectively two first sidewalls, the main body defining a groove among the two first sidewalls and the second sidewall, the groove being configured for fixedly receiving a hard disk, at least one of the two first sidewalls defining a limiting slot, wherein a first direction is defined as a direction from the two first sidewalls to the second sidewall, and a second direction is defined as an opposite direction of the first direction;
a rotation member comprising two rotation arms, at least one of the two rotation arms defining a latching slot, the two rotation arms rotatably connected to the respectively two first sidewalls, the fixing structure is switched between a first state and a second state by the rotation member; and
at least one latching post fixed to the carrier, each of the at least one latching post being movably disposed in a corresponding one of the limiting slot and a corresponding one of the latching slot;
wherein when the fixing structure is switched from the second state to the first state, the two rotation arms are parallel to the first direction, and each of the limiting slot abuts against a corresponding one of the at least one latching post, thereby the main body is movable along the first direction;
wherein when the fixing structure is switched from the first state to the second state, the two rotation arms are angled with the first direction, and each of the limiting slot abuts against a corresponding one of the at least one latching post, thereby each of the at least one latching post is disengaged with the corresponding one of the latching slot, and the main body is movable along the second direction.

9. The server chassis of claim 8, wherein each of the latching slot comprises a first inner wall and a second inner wall, the first inner wall and the second inner wall form an acute angle therebetween; when the fixing structure is switched from the second state to the first state, each first inner wall abuts against a corresponding one of the at least one latching post; when the fixing structure is switched from the first state to the second state, each second inner wall abuts against a corresponding one of the at least one latching post.

10. The server chassis of claim 8, wherein each of the limiting slot comprises a first slot portion and a second slot portion, each of the first slot portion extends through a bottom of a corresponding one of the two first sidewalls, each of the second slot portion communicates with a corresponding one of the first slot portion, along the first direction, each of the first slot portion is narrower than the corresponding one of the second slot portion, a limiting bar is formed near the bottom of the corresponding one of the two first sidewalls;
when in the first state, each of the limiting bar is disposed under a corresponding one of the latching post; when in the second state, each of the at least one latching post moves through the second slot portion and then through the first slot portion.

11. The server chassis of claim 8, wherein the two rotation arms rotate about 45 degrees to switch between the first state and the second state.

12. The server chassis of claim 8, wherein the rotation member further comprises a handle connecting between the two rotation arms.

13. The fixing structure of claim 12, wherein when in the first state, the handle and the second sidewall are connected to each other by snap fit or magnetic adsorption.

14. The server chassis of claim 8, wherein the fixing structure further comprises at least one screw bolt, each of the at least one screw bolt is configured to fix a corresponding one of the two first sidewall to the hard disk.
